(19) United States
(12) Patent Application Publication
(10) Pub. No.: US 2025/0096136 A1
(43) Pub. Date: Mar. 20, 2025

(54) DEVICES, SYSTEMS, AND METHODS FOR A PROGRAMMABLE THREE-DIMENSIONAL SEMICONDUCTOR POWER DELIVERY NETWORK

(71) Applicants: Advanced Micro Devices, Inc., Santa Clara, CA (US); Xilinx, Inc., San Jose, CA (US)

(72) Inventors: Divya Madapusi Srinivas Prasad, Santa Clara, CA (US); Gabriel H. Loh, Bellevue, WA (US); Richard Schultz, Ft. Collins, CO (US); Jeffrey Richard Rearick, Ft. Collins, CO (US); Shidhartha Das, Milton Keynes (GB); Suresh Ramalingam, San Jose, CA (US)

(73) Assignees: Advanced Micro Devices, Inc., Santa Clara, CA (US); Xilinx, Inc., San Jose, CA (US)

(21) Appl. No.: 18/471,114

(22) Filed: Sep. 20, 2023

(51) Int. Cl. H01L 23/528; H01L 23/48

(52) U.S. Cl. CPC H01L 23/5286; H01L 23/481

(57) ABSTRACT

A disclosed semiconductor device includes (1) a silicon stack comprising a front-side Back-End-of-Line (BEOL) stack and a back side BEOL stack, the front-side BEOL stack comprising a plurality of signal routes and the back-side BEOL stack comprising a plurality of power delivery routes, and (2) a plurality of auxiliary power paths formed within the front-side BEOL stack and electrically coupled to the plurality of power delivery routes of the back-side BEOL stack via a plurality of programmable switches, the plurality of power delivery routes, the plurality of programmable switches, and the plurality of auxiliary power paths forming a programmable power delivery network (PDN). Various other apparatuses, systems, and methods of operation are also disclosed.

### BACKGROUND

Power delivery poses significant and unique challenges in the design of semiconductors. Semiconductor engineers must meticulously balance the reliability of executed computing tasks against the intrinsic performance and power capabilities of the system. Moreover, mitigating voltage loss due to electrical resistance in circuits, as well as the impact of changing currents over time, constitutes a substantial hurdle.

The comparatively recent development of back-side power delivery, a technique that involves supplying power from the back side of the Front-End-Of-Line (FEOL), may address some of these concerns. However, while conventional implementations of back-side power may partially address high resistance in the power grid, corner cases may arise which may cause voltage drop or overshoot in the power delivery grid. Moreover, conventional implementations of back-side power may introduce additional complexity and reliability issues, along with a higher likelihood for manufacturing defects and/or variations.

### BRIEF DESCRIPTION OF THE DRAWINGS

The accompanying drawings illustrate a number of example embodiments and are a part of the specification. Together with the following description, these drawings demonstrate and explain various principles of the instant disclosure.

FIG. 1 shows a block diagram of a cross-section view of an example silicon stack that includes a front-side Back-End-Of-Line (BEOL) stack and a back-side BEOL stack.

FIG. 2 shows a block diagram of a cross-section view of an example silicon stack that further includes an example programmable power delivery network (PDN) that includes a plurality of auxiliary power paths formed within a front-side BEOL stack and electrically coupled to a plurality of power delivery routes included in the back-side BEOL stack via a plurality of programmable switches.

FIGS. 3-5 show block diagrams of cross-section views of additional or alternative example configurations for programmable PDNs included in example silicon stacks in accordance with some examples described herein.

FIGS. 6-10 show block diagrams of top views of example configurations for programmable PDNs included in example silicon stacks in accordance with some examples described herein.

FIG. 11 shows a block diagram of a cross-section view of an example silicon stack that further includes a front-side BEOL stack and a back-side BEOL stack with at least one power-delivering through-silicon via (TSV).

FIG. 12 includes a block diagram of an example system for adjusting a programmable PDN.

FIG. 13 includes a flow diagram of an example method for adjusting a programmable PDN in accordance with some of the examples described herein.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the instant disclosure covers all modifications, equivalents, and alternatives falling within the scope of the appended claims.

### DETAILED DESCRIPTION OF EXAMPLE IMPLEMENTATIONS

The present disclosure is generally directed to devices, systems, and methods for a programmable three-dimensional semiconductor power delivery network that uses back-side power and front-side routing resistance. The devices, systems, and methods disclosed herein generally implement an innovative back-side power technology, primarily designed to address power delivery challenges in advanced technology nodes. This disclosure proposes physical structures and methodologies to leverage emerging back-side routing options. These structures (i) facilitate packaging solutions that emphasize thermal efficiency over IR drop, by mitigating IR drop on the die, (ii) minimize the effects of manufacturing defects and optimize yield through a programmable PDN unique to each die, and (iii) adapt to the aging effects of the power delivery network, thereby balancing VDD/VSS IR and enhancing performance and power efficiency. Notably, the proposed structures are hybridized, using novel back-side routing and selectively employing front-side routing.

An example implementation can include a silicon stack with a front-side BEOL stack and a back-side BEOL stack. the front-side BEOL stack can include a plurality of signal routes, while the back-side BEOL stack can include a plurality of power delivery routes. The silicon stack can also include a plurality auxiliary power paths formed within the front-side BEOL stack and electrically coupled to the back-side BEOL stack via a plurality of programmable switches. The plurality of power delivery routes, the plurality of programmable switches, and the plurality of auxiliary power paths can form a programmable PDN.

This programmable PDN can incorporate back-side power while dealing with the resistance encountered during front-side routing. Hence, examples of the systems and methods disclosed herein can introduce programmability within these interconnections, with at least one benefit being an ability to balance voltage drain supply (VDD) and voltage source supply (VSS) and/or an ability to reduce the impact of manufacturing variation and defects.

Furthermore, some examples can mitigate and/or manage clock skew. Clock skew can lead to setup and hold time violations, thereby causing system instability. Managing of clock skew can contribute significantly to overall system reliability and performance.

Hence, the apparatuses, systems, and methods disclosed herein not only can address challenges related to power delivery but can also offer additional benefits that can enhance the reliability, performance, and economic efficiency of semiconductor devices.

In one example, a semiconductor device includes a silicon stack, and the silicon stack includes a front-side BEOL stack and a back-side BEOL stack. The front-side BEOL stack includes a plurality of signal routes and the back-side BEOL stack includes a plurality of power delivery routes. A plurality of auxiliary power paths are formed within the front-side BEOL stack and electrically coupled to the plurality of power delivery routes of the back-side BEOL stack via a plurality of programmable switches, and the plurality of power delivery routes, the plurality of programmable switches, and the plurality of auxiliary power paths form a programmable power delivery network (PDN).

Another example can be the previously described example semiconductor device, where a first auxiliary power path included in the plurality of auxiliary power paths is electrically coupled, via a first switch included in the plurality of programmable switches, to a positive supply voltage terminal, a second auxiliary power path included in the plurality of auxiliary power paths is electrically coupled, via a second switch included in the plurality of programmable switches, to a negative supply voltage terminal, and when electrical power is applied to the silicon stack via the plurality of power delivery routes and the first switch and the second switch are both in a closed position, a power supply voltage flows via the first auxiliary power path and the second auxiliary power path between the positive supply voltage terminal and the negative supply voltage terminal.

Another example can be the semiconductor device of any of the previously described example semiconductor devices, wherein at least one of the plurality of power delivery routes included in the BEOL stack includes at least one defect that inhibits power delivery via the power delivery route. When the electrical power is applied to the silicon stack via the plurality of power delivery routes and the first switch and the second switch are both in the closed position, power supply voltage bypasses the power delivery route that includes the defect.

Another example can be the semiconductor device of any of the previously described example semiconductor devices, wherein a first auxiliary power path included in the plurality of auxiliary power paths is electrically coupled, via a first switch included in the plurality of programmable switches, to a first clock signal terminal, and a second auxiliary power path included in the plurality of auxiliary power paths is electrically coupled, via a second switch included in the plurality of programmable switches, to a second clock signal terminal. When electrical power is applied to the silicon stack via the plurality of power delivery routes and the first switch and the second switch are both in a closed position, a clock signal propagates between the first clock signal terminal and the second clock signal terminal via the first auxiliary power path and the second auxiliary power path.

Another example can be the semiconductor device of any of the previously described example semiconductor devices, wherein the plurality of power delivery routes included in the back-side BEOL stack are disposed parallel to one another along a first direction and in a first common plane; and the plurality of auxiliary power paths formed within the front-side BEOL stack are disposed parallel to one another in a second common plane parallel to the first common plane and in a second direction that is orthogonal to the first direction.

Another example can be the semiconductor device of any of the previously described example semiconductor devices, wherein each of the plurality of programmable switches, when in a closed position, electrically couples at least one of the plurality of power delivery routes to at least one of the plurality of auxiliary power paths.

Another example can be the semiconductor device of any of the previously described example semiconductor devices, wherein the semiconductor device further includes (1) a carrier wafer layer, (2) a thermal oxide bond layer, formed between and bonding the carrier wafer layer and the front-side BEOL stack, (3) an active interposer die (AID) layer, and (4) a hybrid copper bond layer formed between and bonding the back-side BEOL stack and the AID layer.

Another example can be the semiconductor device of any of the previously described example semiconductor devices, wherein (1) the semiconductor device further includes a TSV electrically coupled to the AID layer and electrically coupled via at least one of the programmable switches to a terminal included in the back-side BEOL, and (2) the AID layer is configured to supply power to the power delivery route by way of the TSV through the silicon stack.

Another example can be the semiconductor device of any of the previously described example semiconductor devices, wherein (1) the semiconductor device further includes an additional TSV electrically coupled to the AID layer and electrically coupled via at least one of the programmable switches to an additional terminal included in the back-side BEOL, and (2) the AID layer is configured to drain power by way of the additional TSV through the silicon stack.

In one example, a method includes receiving an instruction to adjust a programmable PDN included in a semiconductor device, wherein (1) the semiconductor device includes a silicon stack including a front-side BEOL stack and a back-side BEOL stack, the front-side BEOL stack including a plurality of signal routes and the back-side BEOL stack including a plurality of power delivery routes, and (2) the programmable PDN includes the plurality of power delivery routes and a plurality of auxiliary power paths formed within the front-side BEOL stack and electrically coupled to the plurality of power delivery routes of the back-side BEOL stack via a plurality of programmable switches. The method also includes adjusting the programmable PDN in response to receiving the instruction.

Another example can be the previously described example method, wherein adjusting the programmable PDN includes adjusting an activation state of at least one of the plurality of programmable switches.

Another example can be any of the previously described example methods, wherein (1) the method further includes detecting, within the programmable PDN, a change in resistance of greater than a threshold resistance value, and (2) receiving the instruction to adjust the programmable PDN includes receiving the instruction in response to detecting the change of resistance.

Another example can be any of the previously described example methods, wherein detecting the change in resistance of greater than the threshold resistance value within the programmable PDN includes detecting the change in resistance within at least one of the power delivery routes included in the back-side BEOL.

Another example can be any of the previously described example methods, further including determining, based on detecting the change in resistance of greater than the threshold value, that a defect exists within the power delivery route.

Another example can be any of the previously described example methods, wherein adjusting the programmable PDN includes adjusting the programmable PDN to bypass the defect within the power delivery route.

In one example, a system includes a semiconductor device. The semiconductor device includes (1) a silicon stack including a front-side BEOL stack and a back-side BEOL stack, the front-side BEOL stack including a plurality of signal routes and the back-side BEOL stack including a plurality of power delivery routes, and (2) a plurality of auxiliary power paths formed within the front-side BEOL stack and electrically coupled to the plurality of power delivery routes of the back-side BEOL stack via a plurality of programmable switches, the plurality of power delivery routes, the plurality of programmable switches, and the plurality of auxiliary power paths forming a programmable PDN. The example system also includes a control device communicatively coupled to the programmable PDN. The control device includes (1) a receiving module, stored in memory, that receives an instruction to adjust the programmable PDN included in the silicon stack, (2) an adjusting module, stored in memory, that adjusts the programmable PDN in response to receiving of the instruction, and (3) at least one physical processor that executes the receiving module and the adjusting module.

Another example can be the previously described example system, wherein the adjusting module adjusts the programmable PDN by adjusting an activation state of at least one of the plurality of programmable switches.

Another example can be any of the previously described example systems, wherein the receiving module (1) further detects, within the programmable PDN, a change in resistance of greater than a threshold resistance value, and (2) receives the instruction to adjust the programmable PDN by receiving the instruction in response to detecting the change of resistance.

Another example can be any of the previously described example systems, wherein the receiving module detects the change in resistance of greater than the threshold resistance value within the programmable PDN by detecting the change in resistance within at least one of the power delivery routes included in the back-side BEOL.

Another example can be any of the previously described example systems, wherein the adjusting module adjusts the programmable PDN by adjusting the programmable PDN to bypass a defect within the power delivery route.

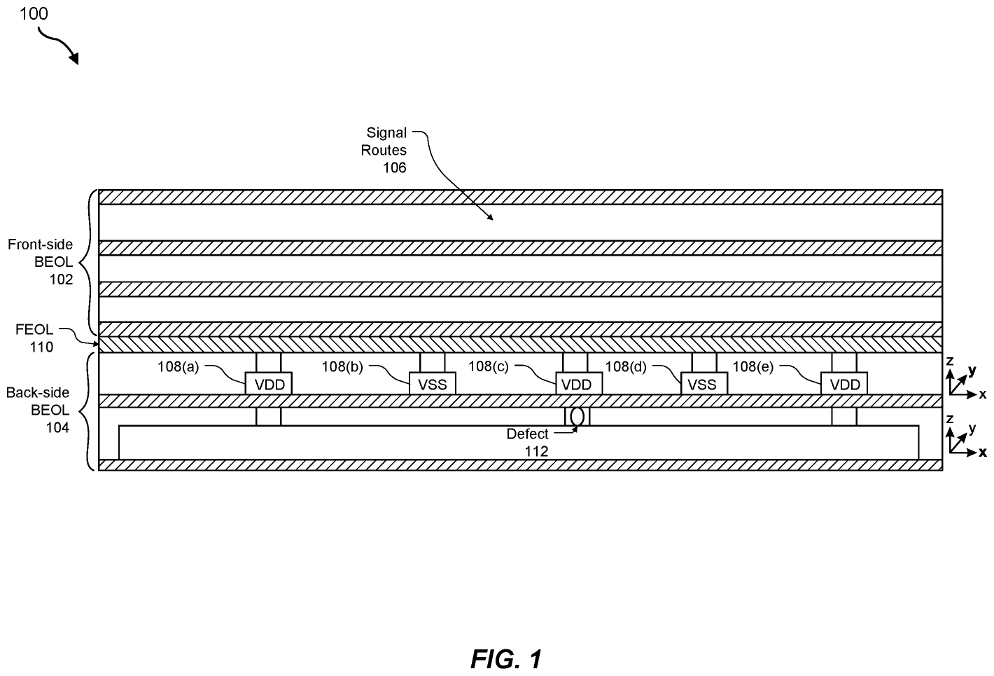

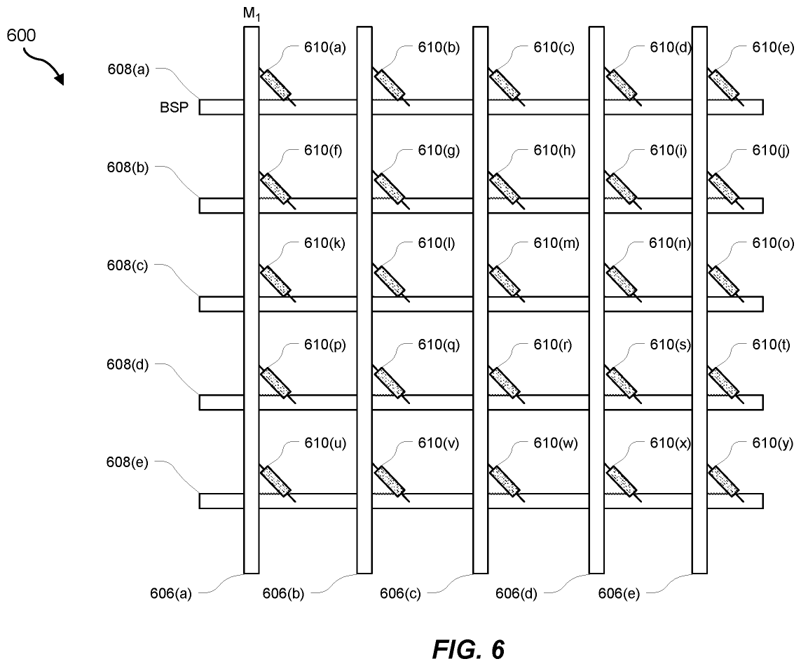

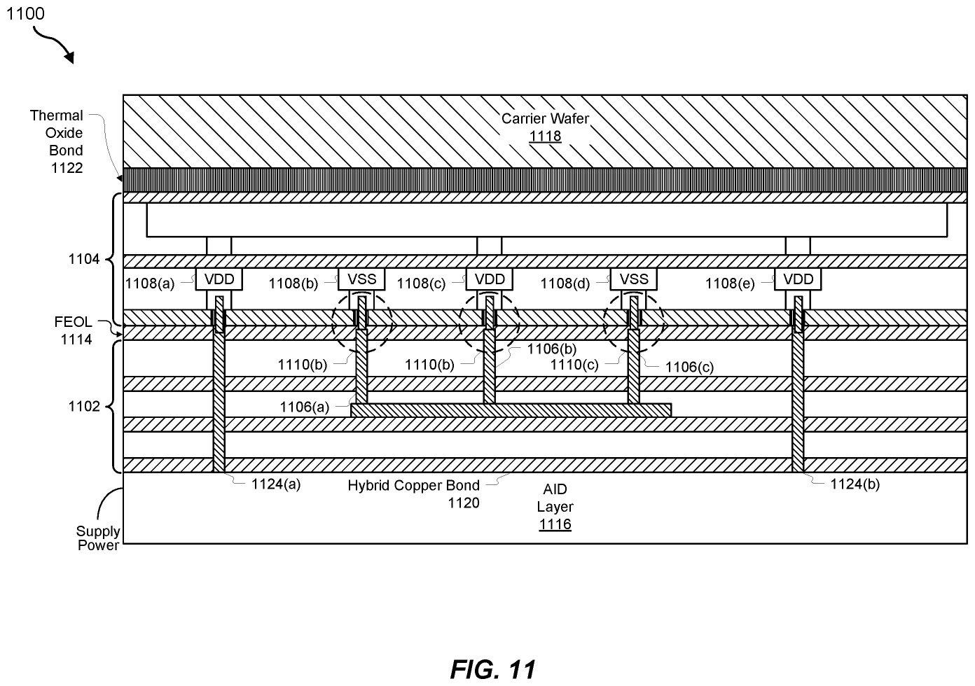

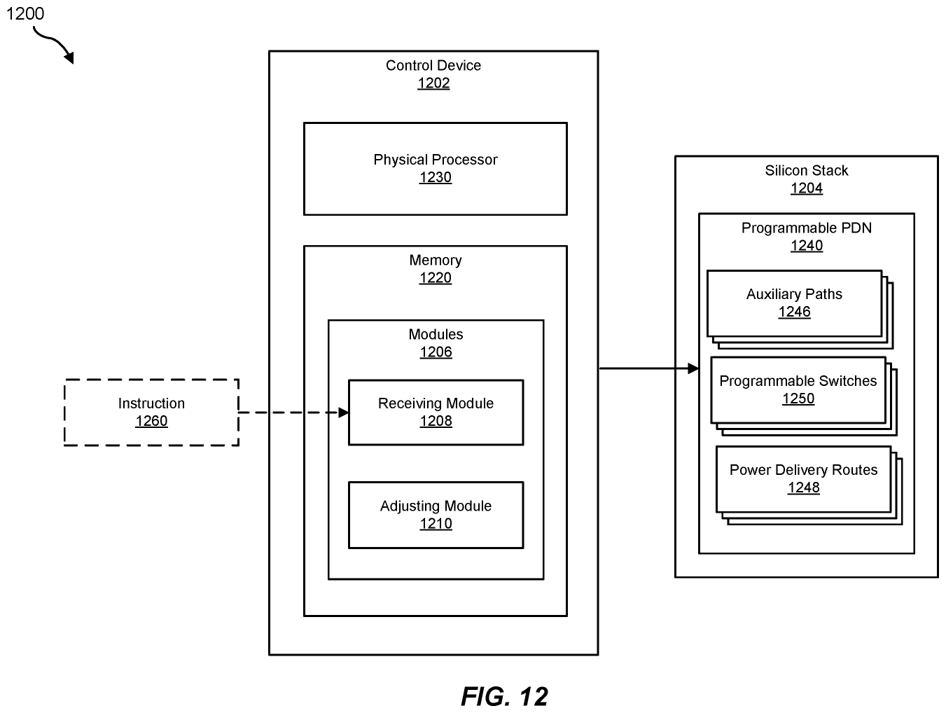

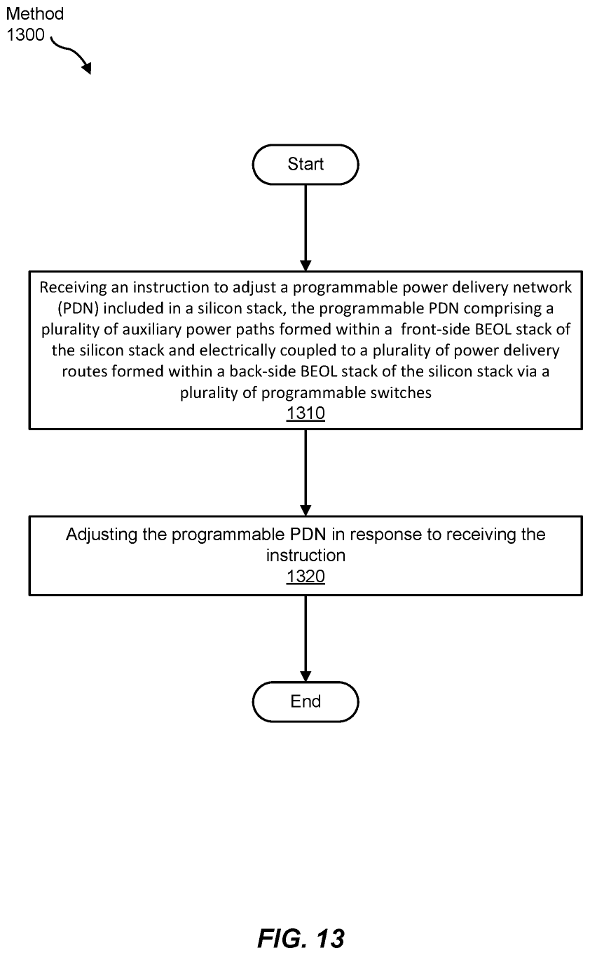

The following will describe, in relation to FIG. 1 to 13, the various different aspects of an example silicon stack and a programmable PDN. FIGS. 1-5 provide various cross-section views of silicon stacks that include front-side and back-side BEOL stacks with programmable PDNs. Likewise, FIGS. 6-10 provide top views of configurations of portions of programmable PDNs. FIG. 11 shows a silicon stack with front-side and back-side BEOL stacks that includes at least one power-delivering TSV. Finally, FIGS. 12-13 illustrate block diagrams of a system for adjusting a programmable PDN and a flowchart illustrating a method for adjusting a programmable PDN, respectively.

FIG. 1 shows a block diagram of a cross-section view of an example silicon stack 100 that includes a front-side BEOL stack 102 and a back-side BEOL stack 104. Although not shown in detail in FIG. 1, front-side BEOL stack 102 can include a plurality of signal routes 106. Likewise, back-side BEOL stack 104 can include a plurality of power delivery routes 108 (e.g., power delivery route 108(a) through 108(e)). Power delivery routes 108 are shown in the example illustrated in FIG. 1 as alternating VSS and VDD terminals. This is by way of example only, as additional or alternative configurations for power delivery routes 108 will be described in greater detail below. As shown, example silicon stack 100 can also include at least one FEOL layer 110 that can include one or more transistors (not shown).

The term “silicon stack,” as used herein, can refer to a layered structure of a semiconductor device, typically composed of several thin layers of silicon and other materials. These layers can include the front-side and back-side BEOL stacks, which respectively contain signal routes and power delivery routes, among other components. The structure supports the device's various functionalities, such as signal transmission and power delivery.

The term “Front-End-of-Line,” as used herein, can generally refer to a first or early stage or portion of the IC production process. This can generally be where the individual devices (e.g., transistors) can be patterned in the semiconductor. FEOL can generally involve steps such as doping, implantation, and etching of the semiconductor material, typically silicon. After the FEOL stage, BEOL stages begin, which involve creating the metal interconnecting wires, essentially turning the devices into a functional circuit.

The term “Back-End-of-Line,” as used herein, can generally refer to a stage in semiconductor chip fabrication where active components (transistors, diodes, etc.), formed in the FEOL process, are interconnected with wiring on the wafer. The BEOL process involves creating metal interconnecting wires, insulating layers, metal layers, and dielectric layers. The term “Back-End-of-Line,” as used herein, distinguishes these later processing steps from the “Front-End-of-Line” where the individual devices (transistors, capacitors, etc.) are formed in the semiconductor. The BEOL is essential for forming the integrated circuits (ICs) that give the chip its functionality.

The term “back-side BEOL stack,” as used herein, can generally refer to a structure that is part of the semiconductor device, specifically situated on the side opposite to the front-side BEOL. This back-side BEOL stack typically consists of multiple layers of metal and dielectric materials used for power delivery routes. These power delivery routes provide power to different parts of the integrated circuit on the semiconductor device. These back-side BEOL elements can be crucial for distributing power throughout the semiconductor device and can contribute to its overall performance and functionality.

The term “front-side BEOL stack,” as used herein, can generally refer to a sequence of layers and interconnects fabricated on a front side of a semiconductor wafer during the BEOL stage of semiconductor manufacturing. This stage, which follows the FEOL stage, is where the individual devices created during the FEOL stage can be interconnected to form complete circuits. The front-side BEOL stack can include multiple layers of metal interconnects, insulating layers, and other components, and can facilitate signal routing and power distribution within the integrated circuit.

In the example illustrated in FIG. 1, back-side BEOL stack 104 includes two layers, with Controlled Collapse Chip Connection (C4) connectivity initiating from the bottom (i.e., opposite of front-side BEOL stack 102). FIG. 1 further shows a notably large defect 112 in a VDD via represented by power delivery route 108(c). As depicted in FIG. 1, this sizable defect could potentially lead to an increased IR drop on the VDD rails (e.g., power delivery route 108(a), power delivery route 108(c), and/or power delivery route 108(e)) for a particular lot or die.

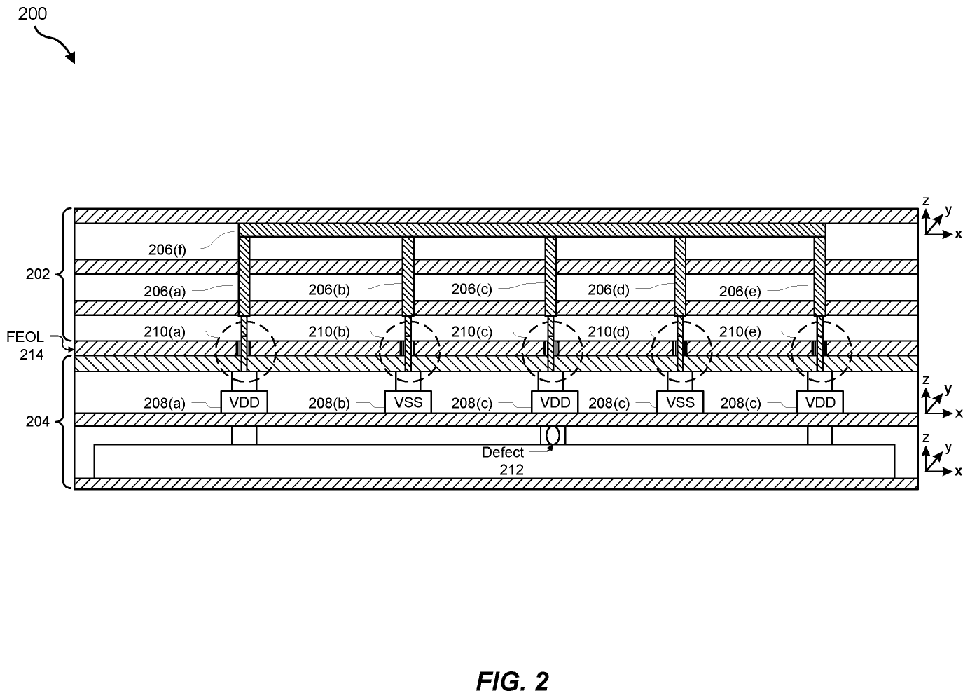

FIG. 2 shows a block diagram of a cross-section view of an example silicon stack 200 that also includes a front-side BEOL stack 202 and a back-side BEOL stack 204. As shown in FIG. 2, example silicon stack 200 further includes an example programmable PDN. As shown, example silicon stack 200 includes a plurality of auxiliary power paths 206 (e.g., auxiliary power path 206(a) through auxiliary power path 206(f)) formed within front-side BEOL stack 202 and electrically coupled to a plurality of power delivery routes 208 (e.g., power delivery route 208(a) through power delivery route 208(e)) included in back-side BEOL stack 204 via a plurality of programmable switches 210 (e.g., programmable switch 210(a) through programmable switch 210(e)). It can be noted that, although programmable switches 210 are shown in FIG. 2 as located within front-side BEOL stack 202 and FEOL 214, this is by way of example only and not intended to limit the scope of this disclosure. Indeed, in some implementations, programmable switches (e.g., programmable switches 210) can be located, partially or fully, within front-side BEOL stack 202, within back-side BEOL stack 204, and/or within FEOL 214.

Programmable switches 210 can be referred to as “programmable” in that each of programmable switches 210 can receive, store, and/or maintain a first configuration state and/or can transition from the first configuration state to a second configuration state in response to receiving an instruction (e.g., from a control device) to do so. The configuration state of each programmable switch 210 can include (1) an open or inactive state whereby the programmable switch restricts or inhibits current from flowing between a power delivery route 208 and a respective auxiliary power path 206, and/or (2) a closed or active state whereby the programmable switch conducts current from the power delivery route 208 and the respective auxiliary power path 206. In some examples, programmable switches 210 can be referred to as “yield-boosting switches”.

Hence, FIG. 2 depicts a programmable PDN, featuring power elements within both the front-side and back-side BEOL stacks. Notably, these connections can be selectively enabled or disabled via the use of yield-boosting switches, allowing for a dynamic adjustment of the power delivery pathways.

By way of example, consider defect 212 situated in the VDD rail of power delivery route 208(c) as depicted in FIG. 2. As with defect 112 depicted in FIG. 1, this sizable defect could potentially lead to an increased IR drop on the VDD rails (e.g., power delivery route 208(a), power delivery route 208(c), and/or power delivery route 208(e)).

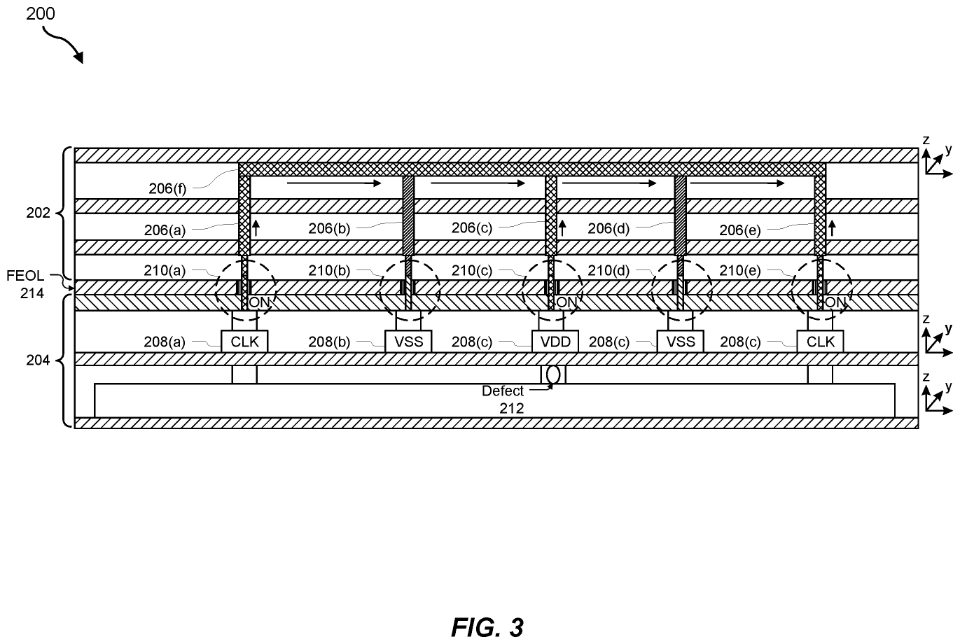

Consequently, specific yield-boosting switches, as illustrated in FIG. 3, can be activated. As shown in FIG. 3, programmable switch 210(a), programmable switch 210(c), and programmable switch 210(e) have transitioned to an active state (denoted in FIG. 3 by “ON”) while programmable switch 210(b) and programmable switch 210(d) have transitioned to an inactive state. This configuration can enable certain pathways in the front-side metal layers (e.g., auxiliary power path 206(a), auxiliary power path 206(c), auxiliary power path 206(e), and auxiliary power path 206(f), each shown in FIG. 3 with a diamond fill pattern) to provide support to the resistance in the back-side VDD grid. Simultaneously, other pathways (e.g., auxiliary power path 206(b) and auxiliary power path 206(d), depicted in FIG. 3 with a fine upward diagonal fill pattern) are deactivated to avoid shorting between the VDD and VSS. A current in the auxiliary power pathways is indicated in FIG. 3 by arrows adjacent to active auxiliary power paths (e.g., auxiliary power path 206(a), auxiliary power path 206(c), auxiliary power path 206(e), and auxiliary power path 206(f)).

It can be important to design the yield-boosting switches in a manner that does not interfere with any operational gates present in the functional design. In some examples, this strategy can be implemented with varying degrees of granularity, and across different metal layers on the front side. In some examples, it can be advantageous to have these auxiliary routes on the upper metals, connected with “superVias” or other structures that can minimize resistance of vias on the front-side BEOL to reach the upper metals. One non-limiting example aim can be to deliver substantial support to the back-side network while utilizing minimal routing resources on the front side.

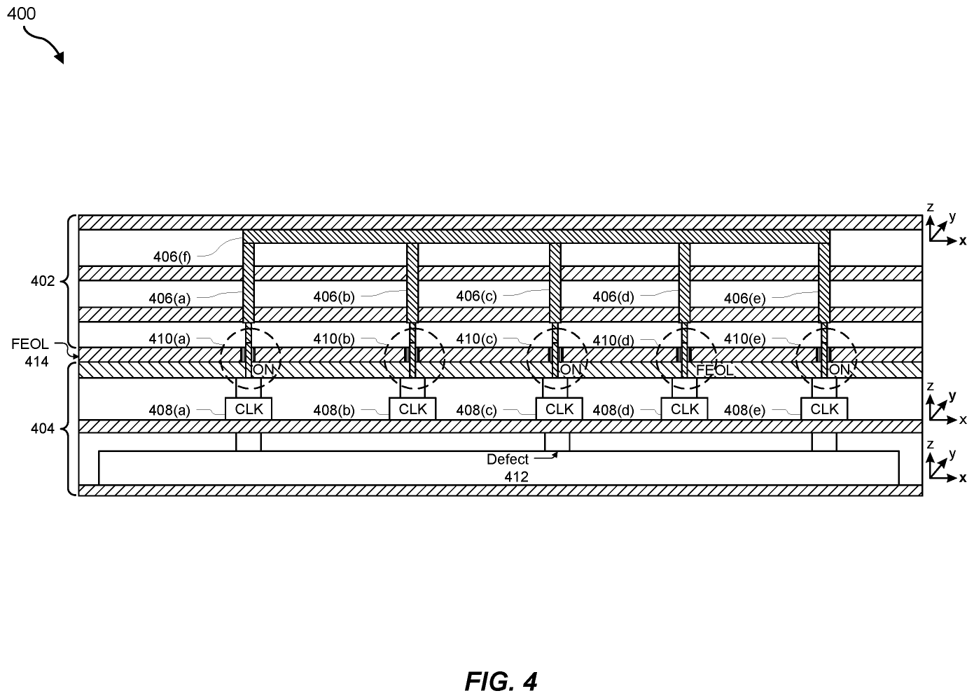

In some examples, the apparatuses, systems, and methods disclosed herein can be implemented within or as part of a clock network, where the back-side BEOL can be used to assist the front-side clock network to alleviate timing/slack. By way of illustration, FIG. 4 shows a block diagram of a cross-section view of an additional example silicon stack 400 with a similar structure as that of example silicon stack 200, but with a clock network. As shown, example silicon stack 400 that includes a front-side BEOL stack 402, a back-side BEOL stack 404, a plurality of auxiliary power paths 406 (e.g., auxiliary power path 406(a) through auxiliary power path 406(f)) formed within front-side BEOL stack 402 and electrically coupled to a plurality of power delivery routes 408 (e.g., power delivery route 408(a) through power delivery route 408(e)) included in back-side BEOL stack 404 via a plurality of programmable switches 410 (e.g., programmable switch 410(a) through programmable switch 410(e)). However, in contrast to example silicon stack 200, power delivery routes 408 are part of a clock network. Thus, the PDN of example stack 400 can be used to assist the front-side clock network to alleviate timing/slack.

As in FIG. 2, although programmable switches 410 are shown in FIG. 4 as located within front-side BEOL stack 402 and FEOL 414, this is by way of example only and not intended to limit the scope of this disclosure. Indeed, in some implementations, programmable switches (e.g., programmable switches 410) can be located, partially or fully, within front-side BEOL stack 402, within back-side BEOL stack 404, and/or within FEOL 414.

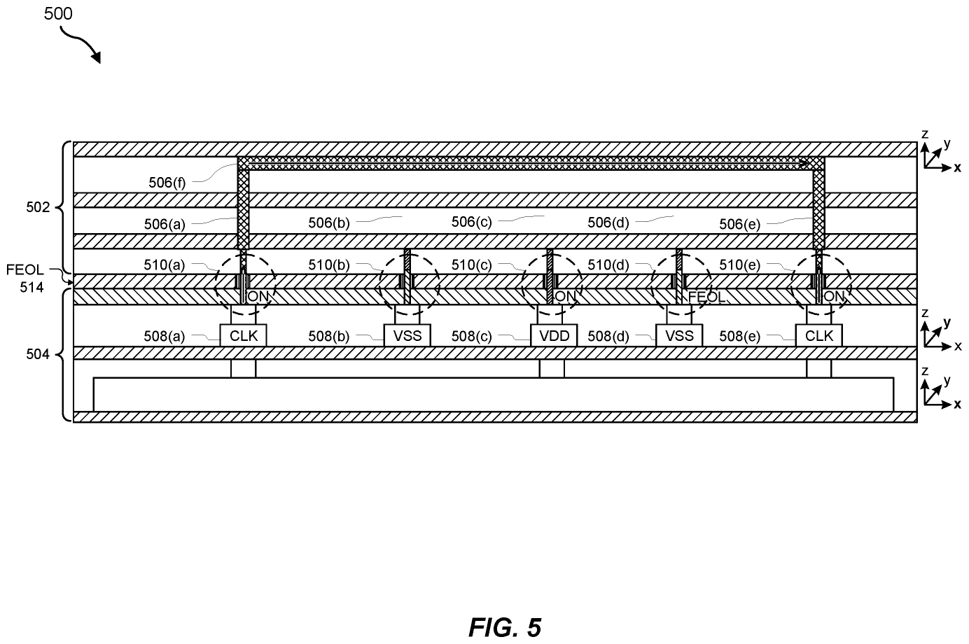

In some examples, the back-side BEOL can be used for both power and clock and connected to the front-side meshes/network through a connectivity switch like the “yield-boosting switches”. As a further illustration, FIG. 5 shows a block diagram of a cross-section view of an additional example silicon stack 500 with a similar structure as that of example silicon stack 200 and example silicon stack 400, but with both power delivery and a clock network connected to the front-side meshes/network. As shown, example silicon stack 500 includes a front-side BEOL stack 502, a back-side BEOL stack 504, a plurality of auxiliary power paths 506 (e.g., auxiliary power path 506(a) through auxiliary power path 506(f)) formed within front-side BEOL stack 502 and electrically coupled to a plurality of power delivery routes 508 (e.g., power delivery route 508(a) through power delivery route 508(e)) included in back-side BEOL stack 404 via a plurality of programmable switches 510 (e.g., programmable switch 510(a) through programmable switch 510(e)). However, in contrast to example silicon stack 200, power delivery route 508(a) and power delivery route 508(e) are part of a clock network, while power delivery route 508(b) and power delivery route 508(d) are VSS vias and power delivery route 508(c) is a VDD via. Thus, as illustrated in this example, the PDN of example stack 500 can be used both for power and to assist the front-side clock network to alleviate timing/slack.

As in FIG. 2 and FIG. 4, although programmable switches 510 are shown in FIG. 5 as located within front-side BEOL stack 502 and FEOL 514, this is by way of example only and not intended to limit the scope of this disclosure. Indeed, in some implementations, programmable switches (e.g., programmable switches 510) can be located, partially or fully, within front-side BEOL stack 502, within back-side BEOL stack 504, and/or within FEOL 514.

FIGS. 6-10 show block diagrams of top views of example configurations for PDNs included in example silicon stacks, such as example silicon stack 200, example silicon stack 400, and/or example silicon stack 500.

FIG. 6 includes a block diagram 600 that provides a simplified representation of just two metal layers within the power grid featuring programmable switches 610 (e.g., programmable switch 610(a) through programmable switch 610(y)). These yield-boosting switches can include or can be like any of programmable switches 210, programmable switches 410, and/or programmable switches 510. In this example, the Back-Side Power (BSP) layers (e.g., power delivery route 608(a) through power delivery route 608(e)) can be utilized as VDD/VSS rails, while the M1 metal layer, situated above the standard-cell abstraction, is the first layer employed for auxiliary connections and/or auxiliary power paths (e.g., auxiliary power path 606(a) through auxiliary power path 606(e)) aimed at yield enhancement. A typical power-delivery network can include grid structures in the lower metal levels to counteract high resistance. This can then transition into totem structures at intermediate metal levels to facilitate more signal routes and can eventually form a grid at the global metal levels to connect to C4 bumps.

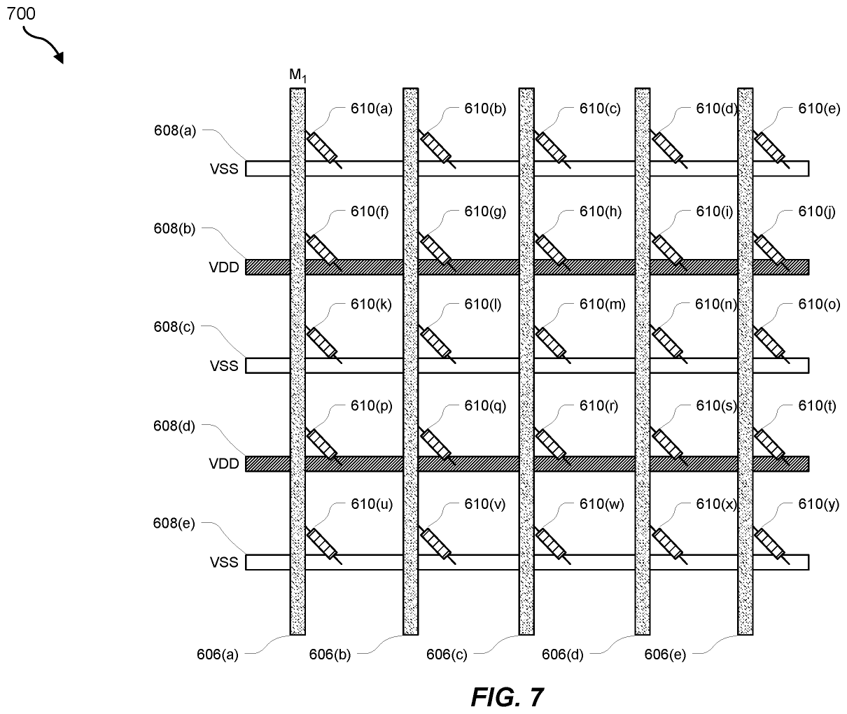

FIG. 7 includes a block diagram 700 that provides a simplified representation of the elements of FIG. 6 in a configuration where all of programmable switches 610 are open or inactive. In this example, the power-grid of auxiliary power paths 606 is disconnected, as indicated by the mottled fill pattern of auxiliary power paths 606. Power delivery routes 608 are shown in use as VDD/VSS rails. Power delivery route 608(b) and power delivery route 608(d) as are shown as in use as VDD rails as indicated by an upward diagonal fill pattern in those power delivery routes, and power deliver route 608(a), power delivery route 608(c), and power delivery route 608(e) are as shown in use as VSS rails, as indicated by an absence of a fill pattern in those power delivery routes.

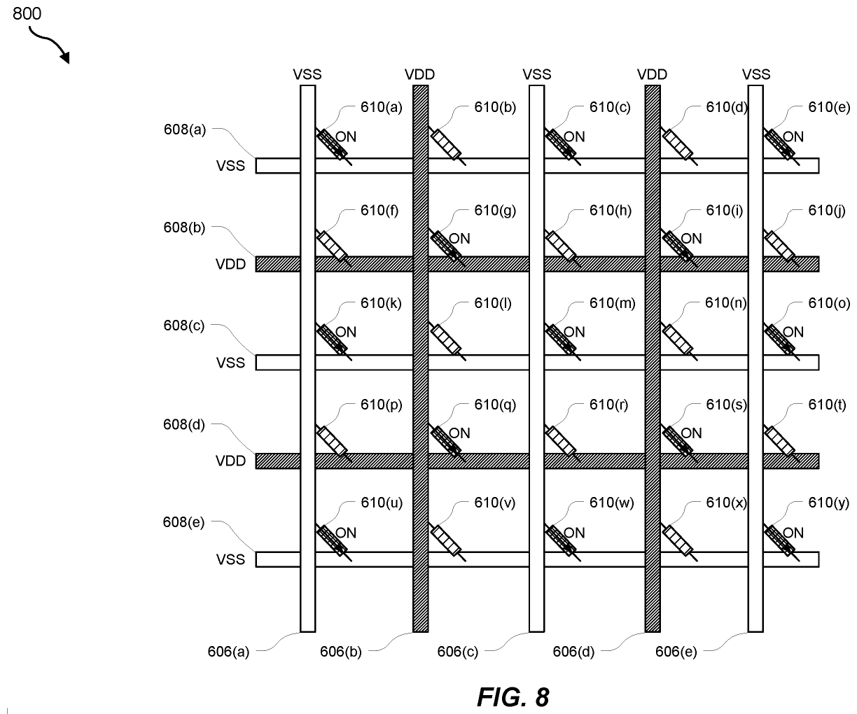

FIG. 8 includes a block diagram 800 that provides a simplified representation of the elements of FIG. 6 in a configuration that resembles a classical power-delivery network that has alternating VDD-VSS-VDD rails. In this example, various of the programmable switches 610 (e.g., programmable switch 610(a), programmable switch 610(c), programmable switch 610(e), and so forth) are in an “on”, open, and/or active position. Hence, various of auxiliary power paths 606 are in use as auxiliary power routes, with auxiliary power path 606(b) and auxiliary power path 606(d) in use as VDD rails (as indicated by an upward diagonal fill pattern) and auxiliary power path 606(a), auxiliary power path 606(c), and auxiliary power path 606(e) in use as VSS rails (as indicated by the absence of a fill pattern).

In some examples, a default configuration of a programmable PDN can employ the auxiliary power paths on the front-side. These paths can be configured to connect to either VDD or VSS, which can ensure efficient use of routing resources and can prevent any unnecessary waste of routing resources.

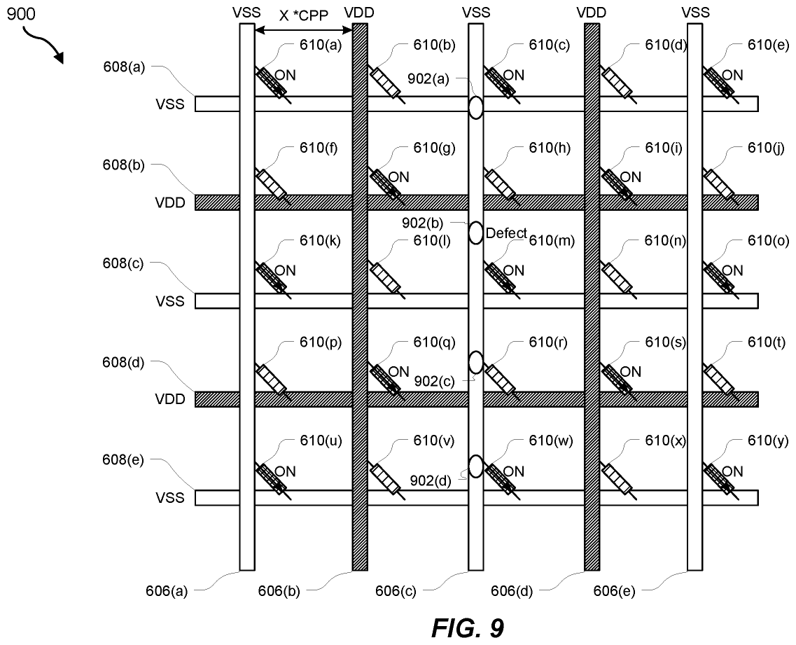

As mentioned above, in some configurations, the systems and methods disclosed herein can be utilized to reduce an impact of manufacturing variation and defects. By way of example, FIG. 9 includes a block diagram 900 that depicts the configuration of FIG. 8, but with the introduction of defects 902 (e.g., defect 902(a), defect 902(b), defect 902(c), and defect 902(d)) on one of the VSS rails. In such an example, FEOL transistors that align with the impacted VSS rail (not shown) will have a high VSS-IR drop, as indicated by the following relationships:

$$R {MAX}_{VSS} = 2 x \times CPP \times \frac{R}{um} \qquad ( 1 )$$

if a defect has a very high resistance, and

$$R {MAX}_{VDD} = x \times CPP \times \frac{R}{um} \qquad ( 2 )$$

In the foregoing relationships, CPP denotes contact poly pitch and x×CPP is a multiplier of the CPP that is considered for spacing the VSS vertical routes. Moreover, R/um represents an effective resistance of the metal per micron length of the route. Hence, in the example shown in FIG. 9, the VSS rails are likely to experience more resistance than the VDD rails due to the presence of defects 902.

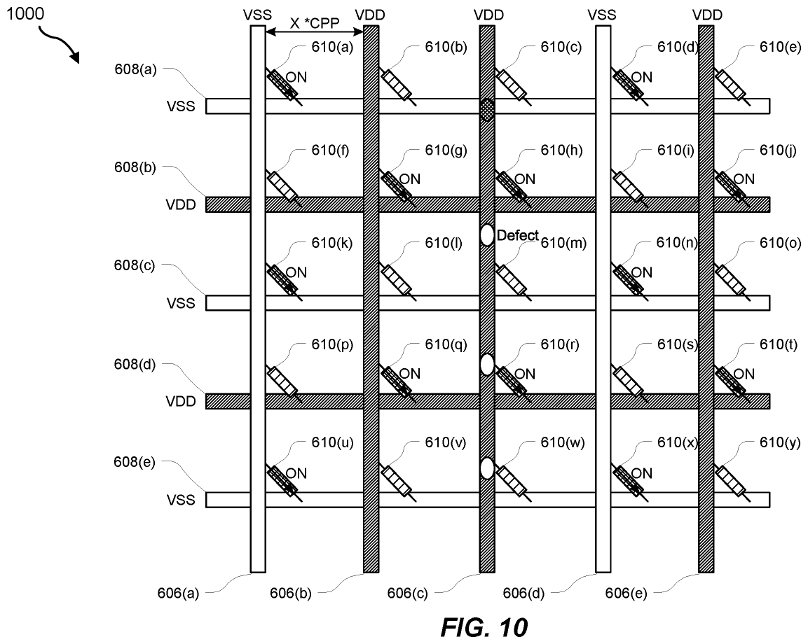

This can be “re-balanced” by “programming” the power-grid differently as shown in FIG. 10. FIG. 10 includes a block diagram 1000 that shows the configuration of FIG. 9, but with programmable switches 610 in a different configuration. As shown, some of programmable switches 610 have transitioned from an activated, closed, or “on” position to a deactivated, open, or “off” position (e.g., programmable switch 610(c), programmable switch 610(m), programmable switch 610(w)) while others of programmable switches 610 have transitioned from a deactivated, open, or “off” position to an activated, closed, or “on” position (e.g., programmable switch 610(h), and programmable switch 610(r)). In this configuration, auxiliary power path 606(c) has transitioned from a VSS rail to a VDD rail. With this configuration, worst-case IR-drop for both VSS and VDD will now be approximately even, and can be approximated by:

$$R {MAX}_{VSS} = 1.5 x \times CPP \times \frac{R}{um} \qquad ( 3 )$$

if the defect rail has a very high resistance, and

$$R {MAX}_{VDD} = 1.5 x \times CPP \times \frac{R}{um} \qquad ( 4 )$$

In some examples, the BEOL switches can have non-optimum performance in comparison to other power delivery options. Even so, the apparatuses, systems, and methods described herein can be well suited for power gating and/or rebalancing techniques where performance is not as significant a concern as in a datapath. Additionally or alternatively, such performance challenges can be offset by a further redesign or reconfiguration of voltage delivery. Considering that some variations of the apparatuses, systems, and methods disclosed herein could result in the repurposing of additional front-side resources to enhance back-side power, a potential solution to the associated performance issues involves improving the efficiency of back-side routing to lessen the load on front-side clock delivery.

In some examples, back-side power technology can involve and/or require thinning of the silicon bulk, leading to an increased spreading resistance and potentially worse thermal effects on die. Hence, in some packaging designs or configurations, a heat spreader can be placed closest to the back-side power routes, and power can be propagated from the front-side BEOL through a via pillar or a TSV. Implementations of the apparatuses, systems, and methods can be incorporated into and/or included in such package designs or configurations, forming a hybrid power delivery network that can be shared between a front-side BEOL and a back-side BEOL.

By way of illustration, FIG. 11 includes a block diagram that shows a cross section of an example silicon stack 1100 with front-side and back-side BEOL stacks that includes at least one power-delivering TSV. As shown, example silicon stack 1100 includes many of the features included in FIG. 1 through FIG. 10, including a front-side BEOL stack 1102, a back-side BEOL stack 1104, a plurality of auxiliary power paths 1106 (e.g., auxiliary power path 1106(a), auxiliary power path 1106(b), and auxiliary power path 1106(c)), a plurality of power delivery routes 1108 (e.g., power delivery route 1108(a), power delivery route 1108(b), power delivery route 1108(c), power delivery route 1108(d), and power delivery route 1108(e)), a plurality of programmable switches 1110 (e.g., programmable switch 1110(a), programmable switch 1110(b), and programmable switch 1110(c)), and a FEOL layer 1114 (e.g., “FEOL 1114” in FIG. 11).

FIG. 11 further shows front-side BEOL stack 1102, back-side BEOL stack 1104, and FEOL layer 1114 sandwiched between an active interposer die (AID) layer 1116 and a carrier wafer 1118, with a hybrid copper bond 1120 bonding the AID layer 1116 to the front-side BEOL stack 1102 and a thermal oxide bond 1122 bonding the back-side BEOL stack 1104 to the carrier wafer 1118. In some examples, an AID can be an interposer routing between one socket or connection to another. In some examples, an AID can additionally or alternatively include active components such as transistors, capacitors, resistors, and so forth.

As shown in FIG. 11, AID layer 1116 can supply power to components included in back-side BEOL stack 1104 by way of one or more TSV 1124 (e.g., TSV 1124(a) and/or TSV 1124(b)). As used herein, the term “Through-Silicon Via” can include a vertical electrical connection that passes partially or completely through a silicon wafer or die. TSVs are high-performance interconnect techniques used as an alternative to wire-bond and flip chips to create 3D packages and 3D integrated circuits. They can offer a high-speed and lower power interconnect solution for stacking and interconnecting dies. In the example shown in FIG. 11, TSV 1124(a) and TSV 1124(b) pass through front-side BEOL stack 1102 and supply power from AID layer 1116 to power delivery route 1108(a) and power delivery route 1108(e), respectively.

The examples and illustrations provided herein show that variations and/or implementations of the apparatuses, systems, and methods disclosed herein can effectively mitigate the IR drop problem and can be utilized to enhance the efficiency of using back-side metal levels (i.e., as compared to exclusively using the back-side metal for VDD and VSS rails or designating the back-side metal for only VSS/VDD and the front side for VDD/VSS, respectively). Hence, variations and/or implementations of the apparatuses, systems, and methods disclosed herein can enable a programmable PDN that can be shared by both front-side and back-side BEOL.

As mentioned above, one or more of the programmable PDNs disclosed herein can be adjusted (e.g., a state of one or more programmable switches can be altered) to enable different configurations or capabilities. FIG. 12 is a block diagram of an example system 1200 for adjusting a programmable PDN. As illustrated in this figure, example system 1200 includes a control device 1202 and a silicon stack 1204. Control device 1202 can include one or more modules 1206 for performing one or more tasks. As will be explained in greater detail below, modules 1206 can include a receiving module 1208 that receives an instruction to adjust the programmable PDN included in a silicon stack (e.g., programmable PDN 1240 included in silicon stack 1204). Control device 1202 can further include an adjusting module 1210 that can, in response to the receiving of the instruction, adjust the programmable PDN.

As also illustrated in FIG. 12, control device 1202 can also include one or more memory devices, such as memory 1220. Memory 1220 generally represents any type or form of volatile or non-volatile storage device or medium capable of storing data and/or computer-readable instructions. In one example, memory 1220 can store, load, and/or maintain one or more of modules 1206. Examples of memory 1220 include, without limitation, Random Access Memory (RAM), Read Only Memory (ROM), flash memory, Hard Disk Drives (HDDs), Solid-State Drives (SSDs), optical disk drives, caches, variations or combinations of one or more of the same, or any other suitable storage memory.

As further illustrated in FIG. 12, control device 1202 can also include one or more physical processors, such as physical processor 1230. Physical processor 1230 generally represents any type or form of hardware-implemented processing unit capable of interpreting and/or executing computer-readable instructions. In one example, physical processor 1230 can access and/or modify one or more of modules 1206 stored in memory 1220. Additionally or alternatively, physical processor 1230 can execute one or more of modules 1206 to facilitate adjusting of a programmable PDN (e.g., programmable PDN 1240 included in silicon stack 1204) Examples of physical processor 1230 include, without limitation, microprocessors, microcontrollers, central processing units (CPUs), Field-Programmable Gate Arrays (FPGAs) that implement softcore processors, Application-Specific Integrated Circuits (ASICs), digital signal processors (DSPs), portions of one or more of the same, variations or combinations of one or more of the same, or any other suitable physical processor.

As further shown in FIG. 12, example system 1200 can also include a silicon stack 1204. Although not shown in FIG. 12, silicon stack 1204 can include a front-side BEOL stack and a back-side BEOL stack. Silicon stack 1204 can also include a programmable PDN 1240, with the programmable PDN including a plurality of power delivery routes 1248 formed within the back-side BEOL stack and a plurality of auxiliary power paths 1246, formed within the front-side BEOL stack and electrically coupled to power delivery routes 1248 via a plurality of programmable switches 1250.

Example system 1200 in FIG. 12 can be implemented in a variety of ways. For example, control device 1202 can represent a computing device that can include and/or be in communication with silicon stack 1204 and/or programmable PDN 1240. In at least one example, control device 1202 can represent a computing device programmed with one or more of modules 1206. As further shown in FIG. 12, receiving module 1206 can receive an instruction 1260 that can instruct and/or direct control device 1202 to adjust a configuration of programmable PDN 1240. Note that instruction 1260 is shown in FIG. 12 in dashed lines, indicating that instruction 1260 is not present in all examples or implementations of example system 1200.

Many other devices or subsystems can be connected to example system 1200 in FIG. 12. Conversely, all of the components and devices illustrated in FIG. 12 need not be present to practice the implementations described and/or illustrated herein. Additionally or alternatively, in some examples, all components of example system 1200 may be incorporated into a single semiconductor device and/or processor package. The devices and subsystems referenced above can also be interconnected in different ways from those shown in FIG. 12. Example system 1200 can also employ any number of software, firmware, and/or hardware configurations. For example, one or more of the variations disclosed herein can be encoded as a computer program (also referred to as computer software, software applications, computer-readable instructions, and/or computer control logic) on a computer-readable medium.

FIG. 13 is a flow diagram of an example computer-implemented method 1300 for adjusting a programmable PDN. The steps shown in FIG. 13 can be performed by any suitable computer-executable code and/or computing system, including system 1200 in FIG. 12 and/or variations or combinations of the same. In one example, each of the steps shown in FIG. 13 can represent an algorithm whose structure includes and/or is represented by multiple sub-steps, examples of which will be provided in greater detail below.

As illustrated in FIG. 13, at step 1310, one or more of the systems described herein can receive an instruction to adjust a programmable PDN. The programmable PDN can be included in a silicon stack and can include a plurality of auxiliary power paths formed within a front-side BEOL stack of the silicon stack and electrically coupled to a plurality of power delivery routes formed within a back-side BEOL stack of the silicon stack via a plurality of programmable switches. For example, receiving module 1208 can, as part of control device 1202, cause control device 1202 to receive instruction 1260 that can instruct control device 1202 to adjust programmable PDN 1240.

Receiving module 1208 can receive instruction 1260 in a variety of ways and/or contexts. For example, receiving module 1208 can receive instruction 1260 via user input, with a user directing control device 1202 (e.g., via a suitable user interface to control device 1202) to adjust programmable PDN 1240 in accordance with instruction 1260. Additionally or alternatively, one or more of modules 1206 (e.g., one or more of receiving module 1208 and/or adjusting module 1210) can monitor programmable PDN and can dynamically generate instruction 1260 in response to detecting and/or identifying a particular condition of programmable PDN 1240 that can be alleviated or resolved by adjusting programmable PDN 1240. For example, as described above in relation to FIG. 9 and FIG. 10, one or more of modules 1206 can identify or detect a defect in one or more of power delivery routes 1248 and can generate instruction 1260 in response to identifying or detecting the defect. Receiving module 1208 can receive instruction 1260, which can cause adjusting module 1210 to adjust programmable PDN 1240 to resolve and/or mitigate an impact of the defect.

Returning to FIG. 13, at step 1320, one or more of the systems described herein can adjust a programmable PDN in response to the receiving of the instruction to adjust the programmable PDN. For example, adjusting module 1210 can adjust programmable PDN 1240 in response to receiving module 1208 receiving instruction 1260.

Adjusting module 1210 can adjust programmable PDN 1240 in a variety of ways. For example, similar to the examples described above in reference to FIGS. 6 through 10, adjusting module 1210 can adjust programmable PDN 1240 by causing one or more of programmable switches 1250 to transition from a first state to a second state, which can activate and/or inactivate one or more of auxiliary power paths 1246 in any of the ways described herein.

In some examples, adjusting module 1210 can adjust connections between the front-side and back-side routes by activating and/or inactivating programmable switches 1250 in a variety of contexts. First, during calibration, these programmable switches and/or auxiliary power paths can help address any issues caused by inconsistencies and defects between different semiconductor dies. Second, these programmable switches and/or auxiliary power paths can be used during regular health checks and recalibrations in the field. For instance, if certain power delivery routes age differently from others, the connections can be reprogrammed to balance out the network. This dynamic adjustment not only saves power and enhances performance based on the workload (or service processor), but also allows for adjustments to be made at a frequency dictated by the control loop time. Such a system can also be referred to as a self-tuning PDN, clock network, or signal network.

The devices, systems, and methods described herein generally disclose a programmable PDN design that leverages back-side power in conjunction with front-side routing resistance. Examples and implementations of the devices, systems, and methods disclosed herein allow for an efficient balance between VDD/VSS routing and offer flexibility to counteract effects of manufacturing variations and defects. Furthermore, the principles disclosed herein can also be extended to alleviate issues related to clock skew.

Examples and implementations of devices, systems, and methods disclosed herein present many benefits over conventional semiconductor power delivery systems. For example, implementations can provide an effective approach to mitigating an impact of process defects or variations within the power grid. Additionally, implementations may contribute to improved silicon performance and performance efficiency post-fabrication. This can result in increased yield, leading to a more cost-effective manufacturing process. Moreover, implementations can alleviate challenges related to BEOL aging and electromigration (EM) that may emerge throughout a semiconductor's or System on a Chip (SoC)'s lifespan. By addressing these issues, implementations of the devices, systems, and methods disclosed herein can enhance the longevity and reliability of semiconductors.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device, comprising:
a silicon stack comprising a front-side Back-End-of-Line (BEOL) stack and a back-side BEOL stack, the front-side BEOL stack comprising a plurality of signal routes and the back-side BEOL stack comprising a plurality of power delivery routes; and
a plurality of auxiliary power paths formed within the front-side BEOL stack and electrically coupled to the plurality of power delivery routes of the back-side BEOL stack via a plurality of programmable switches, the plurality of power delivery routes, the plurality of programmable switches, and the plurality of auxiliary power paths forming a programmable power delivery network (PDN).

2. The semiconductor device of claim 1, wherein:
a first auxiliary power path included in the plurality of auxiliary power paths is electrically coupled, via a first switch included in the plurality of programmable switches, to a positive supply voltage terminal;
a second auxiliary power path included in the plurality of auxiliary power paths is electrically coupled, via a second switch included in the plurality of programmable switches, to a negative supply voltage terminal; and
when electrical power is applied to the silicon stack via the plurality of power delivery routes and the first switch and the second switch are both in a closed position, a power supply voltage flows via the first auxiliary power path and the second auxiliary power path between the positive supply voltage terminal and the negative supply voltage terminal.

3. The semiconductor device of claim 2, wherein:
at least one of the plurality of power delivery routes included in the BEOL stack includes at least one defect that inhibits power delivery via the power delivery route; and
the when the electrical power is applied to the silicon stack via the plurality of power delivery routes and the first switch and the second switch are both in the closed position, power supply voltage bypasses the power delivery route that includes the defect.

4. The semiconductor device of claim 1, wherein:
a first auxiliary power path included in the plurality of auxiliary power paths is electrically coupled, via a first switch included in the plurality of programmable switches, to a first clock signal terminal;
a second auxiliary power path included in the plurality of auxiliary power paths is electrically coupled, via a second switch included in the plurality of programmable switches, to a second clock signal terminal; and
when electrical power is applied to the silicon stack via the plurality of power delivery routes and the first switch and the second switch are both in a closed position, a clock signal propagates between the first clock signal terminal and the second clock signal terminal via the first auxiliary power path and the second auxiliary power path.

5. The semiconductor device of claim 1, wherein:
the plurality of power delivery routes included in the back-side BEOL stack are disposed parallel to one another along a first direction and in a first common plane; and
the plurality of auxiliary power paths formed within the front-side BEOL stack are disposed parallel to one another in a second common plane parallel to the first common plane and in a second direction that is orthogonal to the first direction.

6. The semiconductor device of claim 5, wherein each of the plurality of programmable switches, when in a closed position, electrically couples at least one of the plurality of power delivery routes to at least one of the plurality of auxiliary power paths.

7. The semiconductor device of claim 1, further comprising:
a carrier wafer layer;
a thermal oxide bond layer, formed between and bonding the carrier wafer layer and the front-side BEOL stack;
an active interposer die (AID) layer; and
a hybrid copper bond layer formed between and bonding the back-side BEOL stack and the AID layer.

8. The semiconductor device of claim 7, wherein:
the semiconductor device further comprises a through-silicon via (TSV) electrically coupled to the AID layer and electrically coupled via at least one of the programmable switches to a terminal included in the back-side BEOL; and
the AID layer is configured to supply power to the power delivery route by way of the TSV through the silicon stack.

9. The semiconductor device of claim 8, wherein:
the semiconductor device further comprises an additional TSV electrically coupled to the AID layer and electrically coupled via at least one of the programmable switches to an additional terminal included in the back-side BEOL; and
the AID layer is configured to drain power by way of the additional TSV through the silicon stack.

10. A method comprising:
receiving an instruction to adjust a programmable power delivery network (PDN) included in a semiconductor device, wherein:
the semiconductor device comprises a silicon stack comprising a front-side Back-End-of-Line (BEOL) stack and a back-side BEOL stack, the front-side BEOL stack comprising a plurality of signal routes and the back-side BEOL stack comprising a plurality of power delivery routes; and
the programmable PDN comprises the plurality of power delivery routes and a plurality of auxiliary power paths formed within the front-side BEOL stack and electrically coupled to the plurality of power delivery routes of the back-side BEOL stack via a plurality of programmable switches; and
adjusting the programmable PDN in response to receiving the instruction.

11. The method of claim 10, wherein adjusting the programmable PDN comprises adjusting an activation state of at least one of the plurality of programmable switches.

12. The method of claim 10, wherein:
the method further comprises detecting, within the programmable PDN, a change in resistance of greater than a threshold resistance value; and
receiving the instruction to adjust the programmable PDN comprises receiving the instruction in response to detecting the change of resistance.

13. The method of claim 12, wherein detecting the change in resistance of greater than the threshold resistance value within the programmable PDN comprises detecting the change in resistance within at least one of the power delivery routes included in the back-side BEOL.

14. The method of claim 13, further comprising determining, based on detecting the change in resistance of greater than the threshold value, that a defect exists within the power delivery route.

15. The method of claim 14, wherein adjusting the programmable PDN comprises adjusting the programmable PDN to bypass the defect within the power delivery route.

16. A system comprising:
a semiconductor device comprising:
a silicon stack comprising a front-side Back-End-of-Line (BEOL) stack and a back-side BEOL stack, the front-side BEOL stack comprising a plurality of signal routes and the back-side BEOL stack comprising a plurality of power delivery routes;
a plurality of auxiliary power paths formed within the front-side BEOL stack and electrically coupled to the plurality of power delivery routes of the back-side BEOL stack via a plurality of programmable switches, the plurality of power delivery routes, the plurality of programmable switches, and the plurality of auxiliary power paths forming a programmable power delivery network (PDN);
a control device communicatively coupled to the programmable PDN, the control device comprising:
a receiving module, stored in memory, that receives an instruction to adjust the programmable PDN included in a silicon stack;
an adjusting module, stored in memory, that adjusts the programmable PDN in response to receiving the instruction; and
at least one physical processor that executes the receiving module and the adjusting module.

17. The system of claim 16, wherein the adjusting module adjusts the programmable PDN by adjusting an activation state of at least one of the plurality of programmable switches.

18. The system of claim 16, wherein the receiving module:
further detects, within the programmable PDN, a change in resistance of greater than a threshold resistance value; and
receives the instruction to adjust the programmable PDN by receiving the instruction in response to detecting the change of resistance.

19. The system of claim 18, wherein the receiving module detects the change in resistance of greater than the threshold resistance value within the programmable PDN by detecting the change in resistance within at least one of the power delivery routes included in the back-side BEOL.

20. The system of claim 19, wherein the adjusting module adjusts the programmable PDN by adjusting the programmable PDN to bypass a defect within the power delivery route.
